(19) United States
(12) Patent Application Publication
(10) Pub. No.: US 2009/0263746 A1
(43) Pub. Date: Oct. 22, 2009

(54) METHOD OF MAKING LITHOGRAPHIC PRINTING PLATES WITH SIMPLE PROCESSING

(76) Inventors: Kevin B. Ray, Fort Collins, CO (US); Jianfei Yu, Fort Collins, CO (US); Shashikant Saraiya, Fort Collins, CO (US)

Correspondence Address: Andrew J. Anderson;Patent Legal Staff, Eastman Kodak Company, 343 State Street, Rochester, NY, 14650-2201, US

(21) Appl. No.: 12/104,544

(22) Filed: Apr. 17, 2008

(51) Int. Cl. G03F 7/20

(52) U.S. Cl. 430/302

(57) ABSTRACT

A negative-working lithographic printing plate precursor can be imaged with infrared radiation and processed in a single step using a single processing solution that has a pH of from about 2 to about 11 and contains an anionic surfactant. This single processing solution both develops the imaged precursor and provides a protective coating that need not be rinsed off before lithographic printing. The lithographic printing plate precursor contains a particulate polymeric binder.

### FIELD OF THE INVENTION

This invention provides a method for preparing lithographic printing plates using a single processing solution after imaging, which processing solution both develops and protects the imaged surface of the printing plates before their use in lithographic printing.

### BACKGROUND OF THE INVENTION

In conventional or “wet” lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced. For example, the ink can be first transferred to an intermediate blanket that in turn is used to transfer the ink to the surface of the material upon which the image is to be reproduced.

Imagable elements useful to prepare lithographic printing plates typically comprise at least one imagable layer applied over the hydrophilic surface of a substrate. The imagable layer(s) include one or more radiation-sensitive components that can be dispersed in a suitable binder. Alternatively, the radiation-sensitive component can also be the binder material. Following imaging, either the imaged regions or the non-imaged regions of the imagable layer are removed by a suitable developer, revealing the underlying hydrophilic surface of the substrate. If the imaged (exposed) regions are removed, the element is considered as positive-working. Conversely, if the non-imaged (non-exposed) regions are removed, the element is considered as negative-working. In each instance, the regions of the imagable layer (that is, the image areas) that remain are ink-receptive, and the regions of the hydrophilic surface revealed by the developing process accept water or a fountain solution and repel ink.

Direct digital imaging has become increasingly important in the printing industry. Imagable elements for the preparation of lithographic printing plates have been developed for use with infrared lasers.

Development of negative-working elements using gums is described for example, in EP Publications 1,751,625 (Van Damme et al. published as WO 2005/111727) 1,788,429 (Loccufier et al. et al.), 1,788,430 (Williamson et al.), 1,788,431 (Van Damme et al.), 1,788,434 (Van Damme et al.), 1,788,441 (Van Damme), 1,788,442 (Van Damme), 1,788,443 (Van Damme), 1,788,444 (Van Damme), and 1,788,450 (Van Damme), and WO 2007/057442 (Gries et al.). High pH processing solutions for developing and finishing are described in U.S. Pat. Nos. 5,035,982 (Walls) and 6,649,319 (Fiebag et al.). In addition, copending and commonly assigned U.S. Ser. No. 11/872,772 that was filed Oct. 16, 2007 by K. Ray, Tao, Miller, Clark, and Roth) describes negative-working imagable elements that are sensitive to infrared radiation and can be processed using gum solutions.

Copending and commonly assigned U.S. Ser. No. 11/947,817 (filed Dec. 4, 2007 by K. Ray, Tao, and Clark) describes the use of gums to develop imaged UV-sensitive, negative-working imagable elements that contain specific nonpolymeric diamide additives.

The use of particulate polymeric binders in negative-working imagable elements is described in U.S. Pat. Nos. 6,071,675 (Teng) and 6,899,994 (Huang et al.).

### PROBLEM TO BE SOLVED

While there are a number of commercially useful negative-working lithographic printing plate precursors in the market and many others described in the patent literature, they have generally been developed (processed) using high pH aqueous developers. It would be desirable to avoid such toxic and corrosive processing solutions and to use processing solutions that are more environmentally acceptable to develop and protect the surface of negative-working lithographic printing plate precursors that include particulate polymeric binders in the imagable layer.

### SUMMARY OF THE INVENTION

This invention provides a method for making an image comprising:

A) imagewise exposing a negative-working lithographic printing plate precursor using imaging radiation to provide both exposed and non-exposed regions in the imagable layer,

the lithographic printing plate precursor comprising a substrate and having thereon an imagable layer comprising:

a free-radically polymerizable component,

an initiator composition that is capable of generating free radicals sufficient to initiate polymerization of the free-radically polymerizable component upon exposure to the imaging radiation,

a radiation absorbing compound, and

a primary polymeric binder that is present in the form of discrete particles that are distributed throughout the imagable layer, and

B) applying a single processing solution to the imaged precursor both (1) to remove predominantly only the non-exposed regions, and (2) to provide a protective coating over all of the exposed and non-exposed regions of the resulting lithographic printing plate,

the single processing solution having a pH of from about 2 to about 11 and comprising at least 0.1 weight % of an anionic surfactant.

This invention also provides a method of lithographic printing comprising:

A) imagewise exposing a negative-working lithographic printing plate precursor using imaging radiation to provide both exposed and non-exposed regions in the imagable layer,

the lithographic printing plate precursor comprising a substrate and having thereon an imagable layer comprising:

a free-radically polymerizable component,

an initiator composition that is capable of generating free radicals sufficient to initiate polymerization of said free-radically polymerizable component upon exposure to the imaging radiation,

a radiation absorbing compound, and

a primary polymeric binder that is present in the form of discrete particles that are distributed throughout the imagable layer,

B) applying a single processing solution to the imaged precursor both (1) to remove predominantly only the non-exposed regions, and (2) to provide a protective coating over all of the exposed and non-exposed regions of the resulting lithographic printing plate,

the single processing solution having a pH of from about 2 to about 11 and comprising at least 0.1 weight % of an anionic surfactant,

C) removing excess single processing solution from the lithographic printing plate, and optionally drying said lithographic printing plate, and

D) without removing the protective coating, using the lithographic printing plate for printing an image using a lithographic printing ink.

The lithographic printing plates prepared according to this invention can be used right away for lithographic printing after processing. This simpler and essentially one-step processing procedure provides advantages in work-flow and productivity in preparing the printing plates for use in the pressroom. The single processing step of the invention replaces the traditionally separate development and gumming steps. In addition, the single processing solution is less harmful to the environment and easier to handle and less toxic for disposal. All of these advantages further reduce costs of processing as well.

### DETAILED DESCRIPTION OF THE INVENTION

### Definitions

Unless the context indicates otherwise, when used herein, the terms “lithographic printing plate precursor” and “negative-working lithographic printing plate precursor” are meant to be references to embodiments useful in the practice of the present invention.

In addition, unless the context indicates otherwise, the various components described herein such as “primary polymeric binder”, “secondary polymeric binder”, “free-radically polymerizable component”, “initiator”, “radiation absorbing compound”, “IR dye”, and similar terms also refer to mixtures of such components. Thus, the use of the article “a” or “an” is not necessarily meant to refer to only a single component.

By the term “remove predominantly only said non-exposed regions” during development, we mean that the non-exposed regions of the imagable layer and the corresponding regions of any underlying layers are selectively and preferentially removed by the processing solution, but not the exposed regions to any significant extent (there may be insubstantial removal of the exposed regions).

By “computer-to-press”, we mean the imaging means is carried out using a computer-directed imaging means (such as a laser) directly to the imagable layers without using masking or other intermediate imaging films.

Unless otherwise indicated, the term “single processing solution” is meant to refer to the acidic to slightly alkaline solutions described herein that are used to carry out the processing step B) of the methods of this invention.

Unless otherwise indicated, percentages refer to percents by dry weight, either the dry solids of a layer composition or formulation, or the dry coated weight of a layer (for example, imagable layer or topcoat). Unless otherwise indicated, the weight percent values can be interpreted as for either a layer formulation or a dried layer coating.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

Unless otherwise indicated, the term “polymer” refers to high and low molecular weight polymers including oligomers and includes homopolymers and copolymers.

The term “copolymer” refers to polymers that are derived from two or more different monomers. That is, they comprise recurring units having at least two different chemical structures.

The term “backbone” refers to the chain of atoms in a polymer to which a plurality of pendant groups can be attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Uses

The method of this invention is used primarily to provide lithographic printing plates that can be used in lithographic printing operations as described in more detail below. In general, the lithographic printing plate precursors comprise a substrate, an imagable layer, and an optional topcoat or outermost oxygen-barrier layer disposed over the imagable layer.

### Substrate

The lithographic printing plate precursors are formed by suitable application of an imagable layer formulation or composition onto a suitable substrate. This substrate can be an untreated or uncoated support but it is usually treated or coated in various ways as described below to provide a highly hydrophilic surface prior to application of the imagable layer composition. The substrate comprises a support that can be composed of any material that is conventionally used to prepare lithographic printing plate precursors. The substrate can be treated to provide an “interlayer” for improved adhesion or hydrophilicity, and the inner layer formulation is applied over the interlayer.

The substrate is usually in the form of a sheet, film, or foil, and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports may be modified on one or both surfaces with a “subbing” layer to enhance hydrophilicity, or paper supports may be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

A useful substrate is composed of an aluminum-containing support that may be coated or treated using techniques known in the art, including physical graining, electrochemical graining, chemical graining, and anodizing. For example, the aluminum sheet can be anodized using phosphonic acid or sulfuric acid using conventional procedures.

An optional interlayer may be formed by treatment of the aluminum support with, for example, a silicate, dextrine, calcium zirconium fluoride, hexafluorosilicic acid, phosphate/fluoride, poly(vinyl phosphonic acid) (PVPA), vinyl phosphonic acid-acrylic acid copolymer, poly(acrylic acid), or (meth)acrylic acid copolymer, or mixtures thereof. For example, the grained and/or anodized aluminum support can be treated with poly(phosphonic acid) using known procedures to improve surface hydrophilicity to provide a lithographic hydrophilic substrate.

The thickness of the substrate can be varied but should be sufficient to sustain the wear from printing and thin enough to wrap around a printing form. Such embodiments typically include a treated aluminum foil having a thickness of from about 100 to about 600 μm.

The backside (non-imaging side) of the substrate may be coated with antistatic agents and/or slipping layers or a matte layer to improve handling and “feel” of the imagable element.

The substrate can also be a cylindrical surface having the imagable layers applied thereon, and thus be an integral part of the printing press or a sleeve that is incorporated onto a press cylinder. The use of such imaged cylinders is described for example in U.S. Pat. No. 5,713,287 (Gelbart).

### Imagable Layer Composition

The imagable layer used in the lithographic printing plate precursors is generally composed of a radiation-sensitive composition having several components. For example, the radiation-sensitive composition (and imagable layer) comprises one or more free radically polymerizable components, each of which contains one or more free radically polymerizable groups that can be polymerized using free radical initiation. For example, such secondary free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used.

Suitable ethylenically unsaturated compounds that can be polymerized or crosslinked include ethylenically unsaturated polymerizable monomers that have one or more of the polymerizable groups, including unsaturated esters of alcohols, such as acrylate and methacrylate esters of polyols. Oligomers and/or prepolymers, such as urethane acrylates and methacrylates, epoxide acrylates and methacrylates, polyester acrylates and methacrylates, polyether acrylates and methacrylates, and unsaturated polyester resins can also be used. In some embodiments, the secondary free radically polymerizable component comprises carboxy groups.

Useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers. Free radically polymerizable compounds include those derived from urea urethane(meth)acrylates or urethane(meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), Sartomer 415 [ethoxylated (20)trimethylolpropane triacrylate], and Sartomer 499 [ethoxylated (6) trimethylolpropane triacrylate] that are available from Sartomer Company, Inc.

Numerous other free radically polymerizable compounds are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (noted above), beginning with paragraph [0170], and in U.S. Pat. Nos. 6,309,792 (Hauck et al.), 6,569,603 (Furukawa), and 6,893,797 (Munnelly et al.).

The free radically polymerizable component can be present in the radiation-sensitive composition at a weight ratio to the primary polymeric binder (described above) of from about 5:95 to about 95:5, from about 10:90 to about 90:10, or from about 30:70 to about 70:30. For example, the free radically polymerizable component can be present in an amount of at least 10 and up to and including 70% based on the total solids in the radiation sensitive composition, or the total dry weight of the imagable layer.

The radiation-sensitive composition also includes an initiator composition that is capable of generating free radicals sufficient to initiate polymerization of all the various free radically polymerizable components upon exposure of the composition to imaging radiation. The initiator composition is generally responsive to electromagnetic imaging radiation in the ultraviolet, visible, infrared, or near infrared spectral regions, corresponding to the spectral range of at least 150 nm and up to and including 1500 nm. More typically, they are responsive to infrared radiation of at least 700 nm and up to and including 1400 nm (for example from about 750 to about 1250 nm). Initiator compositions are used that are appropriate for the desired imaging wavelength(s).

In general, suitable initiator compositions comprise compounds that include but are not limited to, amines (such as alkanol amines), thiol compounds, anilinodiacetic acids or derivatives thereof, N-phenyl glycine and derivatives thereof, N,N-dialkylaminobenzoic acid esters, N-arylglycines and derivatives thereof (such as N-phenylglycine), aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, alkyltriarylborates, trihalogenomethylarylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts). Other known initiator composition components are described for example in U.S. Patent Application Publication 2003/0064318 (noted above).

Co-initiators can also be used, such as metallocenes (such as titanocenes and ferrocenes), polycarboxylic acids, haloalkyl triazines, thiols, or mercaptans (such as mercaptotriazoles), borate salts, and photooxidants containing a heterocyclic nitrogen that is substituted by an alkoxy or acyloxy group, as described in U.S. Pat. No. 5,942,372 (West et al.).

In some embodiments, useful initiator compositions include a combination of a 2,4,5-triarylimidazolyl dimer and a thiol compound such as either 2,2′-bis(o-chlorophenyl)-4,4′,5,5′-tetraphenylbiimidazole or 2,2′-bis(o-chlorophenyl)-4,4′,5,5′-tetra(m-methoxyphenyl)biimidazole in combination with a thiol compound such as a mercaptotriazole.

Useful radiation-sensitive compositions include an onium salt including but not limited to, a sulfonium, oxysulfoxonium, oxysulfonium, sulfoxonium, ammonium, selenonium, arsonium, phosphonium, diazonium, or halonium salt. Further details of useful onium salts, including representative examples, are provided in U.S. Patent Application Publication 2002/0068241 (Oohashi et al.), WO 2004/101280 (Munnelly et al.), and U.S. Pat. Nos. 5,086,086 (Brown-Wensley et al.), 5,965,319 (Kobayashi), and 6,051,366 (Baumann et al.). For example, suitable phosphonium salts include positive-charged hypervalent phosphorus atoms with four organic substituents. Suitable sulfonium salts such as triphenylsulfonium salts include a positively-charged hypervalent sulfur with three organic substituents. Suitable diazonium salts possess a positive-charged azo group (that is —N═N⁺). Suitable ammonium salts include a positively-charged nitrogen atom such as substituted quaternary ammonium salts with four organic substituents, and quaternary nitrogen heterocyclic rings such as N-alkoxypyridinium salts. Suitable halonium salts include a positively-charged hypervalent halogen atom with two organic substituents. The onium salts generally include a suitable number of negatively-charged counterions such as halides, hexafluorophosphate, thiosulfate, hexafluoroantimonate, tetrafluoroborate, sulfonates, hydroxide, perchlorate, n-butyltriphenyl borate, tetraphenyl borate, and others readily apparent to one skilled in the art.

The halonium salts are useful such as the iodonium salts. In one embodiment, the onium salt has a positively-charged iodonium, (4-methylphenyl)[4-(2-methylpropyl)phenyl]-moiety and a suitable negatively charged counterion. A representative example of such an iodonium salt is available as Irgacure® 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

Useful boron-containing compounds include organic boron salts that include an organic boron anion such as those described in the noted U.S. Pat. No. 6,569,603 that is paired with a suitable cation such as an alkali metal ion, an onium, or a cationic sensitizing dye. Useful onium cations for this purpose include but are not limited to, ammonium, sulfonium, phosphonium, iodonium, and diazonium cations. Iodonium salts such as iodonium borates are useful as initiator compounds in radiation-sensitive compounds that are designed for “on-press” development (described in more detail below). They may be used alone or in combination with various co-initiators such as heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-(p-aminophenyl)-3-mercapto-1,2,4-triazole.

Examples of other useful initiator compositions are described for example in EP 1,182,033 (Fujimaki et al.) and in U.S. Pat. Nos. 6,352,812 (Shimazu et al.) and 6,893,797 (Munnelly et al.).

One class of useful iodonium cations include diaryliodonium cations that are represented by the following Structure (IB):

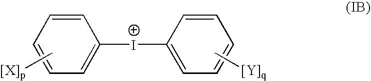

wherein X and Y are independently halo groups (for example, fluoro, chloro, or bromo), substituted or unsubstituted alkyl groups having 1 to 20 carbon atoms (for example, methyl, chloromethyl, ethyl, 2-methoxyethyl, n-propyl, isopropyl, isobutyl, n-butyl, t-butyl, all branched and linear pentyl groups, 1-ethylpentyl, 4-methylpentyl, all hexyl isomers, all octyl isomers, benzyl, 4-methoxybenzyl, p-methylbenzyl, all dodecyl isomers, all icosyl isomers, and substituted or unsubstituted mono- and poly-, branched and linear haloalkyls), substituted or unsubstituted alkyloxy having 1 to 20 carbon atoms (for example, substituted or unsubstituted methoxy, ethoxy, isopropoxy, t-butoxy, (2-hydroxytetradecyl)oxy, and various other linear and branched alkyleneoxyalkoxy groups), substituted or unsubstituted aryl groups having 6 or 10 carbon atoms in the carbocyclic aromatic ring (such as substituted or unsubstituted phenyl and naphthyl groups including mono- and polyhalophenyl and naphthyl groups), or substituted or unsubstituted cycloalkyl groups having 3 to 8 carbon atoms in the ring structure (for example, substituted or unsubstituted cyclopropyl, cyclopentyl, cyclohexyl, 4-methylcyclohexyl, and cyclooctyl groups). Typically, X and Y are independently substituted or unsubstituted alkyl groups having 1 to 8 carbon atoms, alkyloxy groups having 1 to 8 carbon atoms, or cycloalkyl groups having 5 or 6 carbon atoms in the ring, and more preferably, X and Y are independently substituted or unsubstituted alkyl groups having 3 to 6 carbon atoms (and particularly branched alkyl groups having 3 to 6 carbon atoms). Thus, X and Y can be the same or different groups, the various X groups can be the same or different groups, and the various Y groups can be the same or different groups. Both “symmetric” and “asymmetric” diaryliodonium borate compounds are contemplated but the “symmetric” compounds are preferred (that is, they have the same groups on both phenyl rings).

In addition, two or more adjacent X or Y groups can be combined to form a fused carbocyclic or heterocyclic ring with the respective phenyl groups.

The X and Y groups can be in any position on the phenyl rings but typically they are at the 2- or 4-positions on either or both phenyl rings.

Despite what type of X and Y groups are present in the iodonium cation, the sum of the carbon atoms in the X and Y substituents generally is at least 6, and typically at least 8, and up to 40 carbon atoms. Thus, in some compounds, one or more X groups can comprise at least 6 carbon atoms, and Y does not exist (q is 0). Alternatively, one or more Y groups can comprise at least 6 carbon atoms, and X does not exist (p is 0). Moreover, one or more X groups can comprise less than 6 carbon atoms and one or more Y groups can comprise less than 6 carbon atoms as long as the sum of the carbon atoms in both X and Y is at least 6. Still again, there may be a total of at least 6 carbon atoms on both phenyl rings.

In Structure IB, p and q are independently 0 or integers of 1 to 5, provided that either p or q is at least 1. Typically, both p and q are at least 1, or each of p and q is 1. Thus, it is understood that the carbon atoms in the phenyl rings that are not substituted by X or Y groups have a hydrogen atom at those ring positions.

Useful boron-containing anions are organic anions having four organic groups attached to the boron atom. Such organic anions can be aliphatic, aromatic, heterocyclic, or a combination of any of these. Generally, the organic groups are substituted or unsubstituted aliphatic or carbocyclic aromatic groups. For example, useful boron-containing anions can be represented by the following Structure (IB_{Z}):

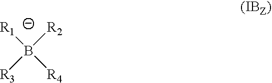

wherein R₁, R₂, R₃, and R₄ are independently substituted or unsubstituted alkyl groups having 1 to 12 carbon atoms (such as methyl, ethyl, n-propyl, isopropyl, n-butyl, isobutyl, t-butyl, all pentyl isomers, 2-methylpentyl, all hexyl isomers, 2-ethylhexyl, all octyl isomers, 2,4,4-trimethylpentyl, all nonyl isomers, all decyl isomers, all undecyl isomers, all dodecyl isomers, methoxymethyl, and benzyl) other than fluoroalkyl groups, substituted or unsubstituted carbocyclic aryl groups having 6 to 10 carbon atoms in the aromatic ring (such as phenyl, p-methylphenyl, 2,4-methoxyphenyl, naphthyl, and pentafluorophenyl groups), substituted or unsubstituted alkenyl groups having 2 to 12 carbon atoms (such as ethenyl, 2-methylethenyl, allyl, vinylbenzyl, acryloyl, and crotonotyl groups), substituted or unsubstituted alkynyl groups having 2 to 12 carbon atoms (such as ethynyl, 2-methylethynyl, and 2,3-propynyl groups), substituted or unsubstituted cycloalkyl groups having 3 to 8 carbon atoms in the ring structure (such as cyclopropyl, cyclopentyl, cyclohexyl, 4-methylcyclohexyl, and cyclooctyl groups), or substituted or unsubstituted heterocyclyl groups having 5 to 10 carbon, oxygen, sulfur, and nitrogen atoms (including both aromatic and non-aromatic groups, such as substituted or unsubstituted pyridyl, pyrimidyl, furanyl, pyrrolyl, imidazolyl, triazolyl, tetrazoylyl, indolyl, quinolinyl, oxadiazolyl, and benzoxazolyl groups). Alternatively, two or more of R₁, R₂, R₃, and R₄ can be joined together to form a heterocyclic ring with the boron atom, such rings having up to 7 carbon, nitrogen, oxygen, or nitrogen atoms. None of the R₁ through R₄ groups contains halogen atoms and particularly fluorine atoms.

Typically, R₁, R₂, R₃, and R₄ are independently substituted or unsubstituted alkyl or aryl groups as defined above, and more typically, at least 3 of R₁, R₂, R₃, and R₄ are the same or different substituted or unsubstituted aryl groups (such as substituted or unsubstituted phenyl groups). For example, all of R₁, R₂, R₃, and R₄ can be the same or different substituted or unsubstituted aryl groups, or all of the groups are the same substituted or unsubstituted phenyl group. Z⁻ can be a tetraphenyl borate wherein the phenyl groups are substituted or unsubstituted (for example, all are unsubstituted phenyl groups).

Some representative iodonium borate compounds include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexylphenyliodonium n-butyltriphenylborate, 4-cyclohexylphenyl-4′-phenyliodonium tetraphenylborate, 2-methyl-4-t-butylphenyl-4′-methylphenyliodonium tetraphenylborate, 4-methylphenyl-4′-pentylphenyliodonium tetrakis [3,5-bis(trifluoromethyl)phenyl]-borate, 4-methoxypheny 1-4′-cyclohexylphenyliodonium tetrakis(pentafluorophenyl)borate, 4-methylphenyl-4′-dodecylphenyliodonium tetrakis(4-fluorophenyl)borate, bis(dodecylphenyl)iodonium tetrakis(pentafluorophenyl)-borate, and bis(4-t-butylphenyl)iodonium tetrakis(1-imidazolyl)borate. Mixtures of two or more of these compounds can also be used in the iodonium borate initiator composition.

Such diaryliodonium borate compounds can be prepared, in general, by reacting an aryl iodide with a substituted or unsubstituted arene, followed by an ion exchange with a borate anion. Details of various preparatory methods are described in U.S. Pat. No. 6,306,555 (Schulz et al.), and references cited therein, and by Crivello, J. Polymer Sci., Part A: Polymer Chemistry, 37, 4241-4254 (1999), both of which are incorporated herein by reference.

The boron-containing anions can also be supplied as part of infrared radiation absorbing dyes (for example, cationic dyes) as described below. Such boron-containing anions generally are defined as described above with Structure (IBz).

The free radical generating compounds in the initiator composition are generally present in the radiation-sensitive composition in an amount of at least 0.5% and up to and including 30%, and typically at least 2 and up to and including about 20%, based on composition total solids or total dry weight of the imagable layer. The optimum amount of the various initiator components may differ for various compounds and the sensitivity of the radiation-sensitive composition that is desired and would be readily apparent to one skilled in the art.

The lithographic printing plate precursor also includes one or more imaging radiation absorbing compounds (or chromophores or sensitizers) that spectrally sensitize the composition to a desired wavelength. In some embodiments, this imparted sensitivity is from about 300 nm and up to and 500 nm, typically from about 350 to about 475 nm and more typically from about 390 to about 430 nm. For example, useful sensitizers for these wavelengths include but are not limited to compounds having the following Formula:

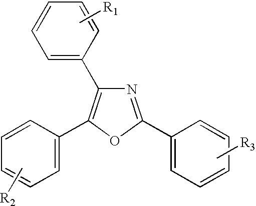

wherein R₁, R₂ and R₃ independently represent a hydrogen atom, alkyl, aryl or aralkyl group that may be substituted, an —NR₄R₅-group (R₄ and R₅ representing an alkyl, aryl or aralkyl group), or —OR₆ group (R₆ representing an alkyl, aryl or aralkyl group). Particularly useful compounds of this Formula contain at least one of substituent R₁, R₂, and R₃ that represents a donor group, such as an amino group (for example, an dialkylamino group). These compounds can be made following the procedure given in DE 1,120,875 (Sues et al.) and EP 129,059 (Hayashida).

Other embodiments include infrared radiation absorbing compounds (“IR absorbing compounds”) that generally absorb radiation from about 700 to about 1200 nm and typically from about 750 to about 1250 nm with minimal absorption at 300 to 600 nm.

Examples of suitable IR dyes include but are not limited to, azo dyes, squarylium dyes, triarylamine dyes, thioazolium dyes, indolium dyes, oxonol dyes, oxazolium dyes, cyanine dyes, merocyanine dyes, phthalocyanine dyes, indocyanine dyes, indotricarbocyanine dyes, hemicyanine dyes, streptocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo)-polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, polymethine dyes, squaraine dyes, oxazole dyes, croconine dyes, porphyrin dyes, and any substituted or ionic form of the preceding dye classes. Suitable dyes are described for example, in U.S. Pat. Nos. 4,973,572 (DeBoer), 5,208,135 (Patel et al.), 5,244,771 (Jandrue Sr. et al.), and 5,401,618 (Chapman et al.), and EP 0 823 327A1 (Nagasaka et al.).

Cyanine dyes having an anionic chromophore are also useful. For example, the cyanine dye may have a chromophore having two heterocyclic groups. In another embodiment, the cyanine dye may have at least two sulfonic acid groups, more particularly two sulfonic acid groups and two indolenine groups. Useful IR-sensitive cyanine dyes of this type are described for example in U.S. Patent Application Publication 2005-0130059 (Tao). A general description of one class of suitable cyanine dyes is shown by the formula in paragraph 0026 of WO 2004/101280 (Munnelly et al.).

In addition to low molecular weight IR-absorbing dyes, IR dye moieties bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. Nos. 6,309,792 (Hauck et al.), 6,264,920 (Achilefu et al.), 6,153,356 (Urano et al.), and 5,496,903 (Watanabe et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (noted above).

Useful IR absorbing compounds include various pigments including carbon blacks such as carbon blacks that are surface-functionalized with solubilizing groups are well known in the art. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful. Other useful pigments include, but are not limited to, Heliogen Green, Nigrosine Base, iron (III) oxides, manganese oxide, Prussian Blue, and Paris Blue. The size of the pigment particles should not be more than the thickness of the imagable layer.

The radiation absorbing compound is generally present in the lithographic printing plate precursor in an amount of at least 0.5% and up to 30 weight % and typically from about 3 to about 25 weight % (based on total dry layer weight). The particular amount needed for this purpose would be readily apparent to one skilled in the art, depending upon the specific compound used and the properties of the alkaline developer to be used. In most embodiments, the radiation absorbing compound is present in the inner layer only, but as noted above, optionally it can be in other locations in addition to or alternatively to, the inner layer.

The radiation-sensitive composition comprises one or more particulate primary polymeric binders. That is, these polymeric binders are present in the radiation-sensitive composition (or imagable layer) in particulate form, meaning that they exist at room temperature as discrete particles, for example in an aqueous dispersion. However, the particles can also be partially coalesced or deformed, for example at temperatures used for drying coated imagable layer formulations. Even in this environment, the particulate structure is not destroyed. The average particle size is generally from about 30 to about 2000 nm and typically the average particle size is from about 60 to about 1000 nm or from about 60 to about 500 nm. The particulate primary polymeric binder is generally obtained commercially and used as an aqueous dispersion having at least 20% and up to 50% solids.

The primary polymeric binders generally have a molecular weight (Mₙ) of at least 2,000 and typically at least 100,000 to about 500,000, or from about 100,000 to about 300,000, as determined by dynamic light scattering.

In addition, the glass transition temperature (Tg) of the particulate primary polymeric binder is generally from about 10 to about 70° C., and in some embodiments, the Tg is from about 25 to about 70° C.

The primary polymeric binder is generally present in the radiation-sensitive composition in an amount of at least 10%, and typically from about 25 to about 70%, based on the total composition (or imagable layer) dry weight. These binders may comprise up to 100% of the dry weight of all polymeric binders (including any secondary polymeric binders).

In some embodiments, the primary polymeric binders are radically polymerizable primary polymeric binders. These primary polymeric binders can be “self-crosslinkable”, by which we mean that a separate free radically polymerizable component is not necessary. Such binders have a backbone comprising multiple (at least two) urethane moieties. In some embodiments, there are at least two of these urethane moieties in each backbone recurring unit. The primary polymeric binders also include side chains attached to the backbone, which side chains include one or more free radically polymerizable groups (such as ethylenically unsaturated groups) that can be polymerized (crosslinked) in response to free radicals produced by the initiator composition (described below). There may be at least two of these side chains per molecule.

In such embodiments, the primary polymeric binders may be substantially free of unreacted isocyanate functional groups, which means that there is less than 0.01 mol of such groups per mole of free radically polymerizable groups in the side chains.

The free radically polymerizable groups (or ethylenically unsaturated groups) can be part of aliphatic or aromatic acrylate side chains attached to the polymeric backbone. Generally, there are at least 2 and up to 20 such groups per molecule, or typically from 2 to 10 such groups per molecule.

This primary polymeric binders can also comprise hydrophilic groups including but not limited to, carboxy, sulfo, or phospho groups, either attached directly to the backbone or attached as part of side chains other than the free radically polymerizable side chains. In most embodiments, the hydrophilic groups, such as carboxy groups, are directly attached to the backbone.

Such primary polymeric binders can also have a solvent resistance as measured when 0.1 g remains insoluble when it is agitated (for example, stirred or shaken) for 24 hours at 20° C. in an aqueous solution of either 2-butoxyethanol or 4-hydroxy-4-methyl-2-pentanone (20% water).

While not intending to limit the scope of the invention, a representative backbone recurring unit of such primary polymeric binders can be illustrated by the following schematic diagram (BINDER UNIT) that shows a single backbone recurring unit inside the brackets, and “n” represents sufficient number of the same or different backbone recurring units to provide a minimum molecular weight, as noted above, of at least 2,000. In (BINDER UNIT), the oval blocks can represent polyester acrylate, epoxy acrylate, or polyether acrylate groups, the square blocks can represent diisocyanate groups, and the rectangular blocks can represent monomeric diol (such as hexane diol) or polymeric diol groups. The illustrated backbone recurring unit has two urethane moieties and at least one hydrophilic carboxy group that is directly attached to the backbone.

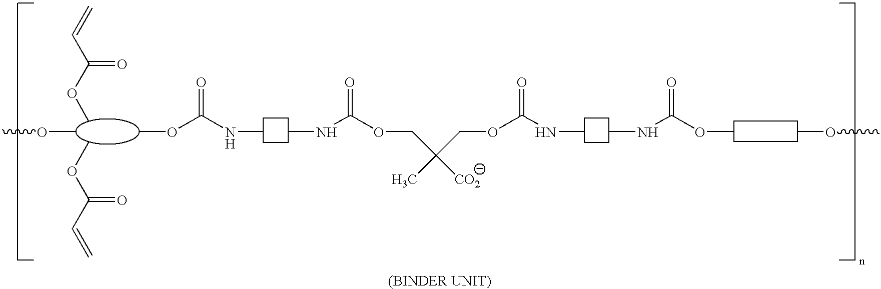

Useful commercial products that comprise primary polymeric binders useful in this invention include but are not limited to, Bayhydrol® UV VP LS 2280, Bayhydrol® UV VP LS 2282, Bayhydrol® UV VP LS 2317, Bayhydrol® UV VP LS 2348, and Bayhydrol® UV XP 2420, that are all available from Bayer MateriaiScience, as well as Laromer™ LR 8949, Laromer™ LR 8983, and Laromer™ LR 9005, that are all available from BASF.

Other useful primary polymeric binders that are particulate in form include poly(urethane-acrylic) hybrids. This hybrid has a molecular weight of from about 50,000 to about 500,000. These hybrids can be either “aromatic” or “aliphatic” in nature depending upon the specific reactants used in their manufacture. Blends of particles of two or more poly(urethane-acrylic) hybrids can also be used. For example, a blend of Hybridur® 570 polymer dispersion with Hybridur® 870 polymer dispersion could be used.

Such poly(urethane-acrylic) hybrid particles generally remain insoluble in the following test:

0.1 g of particles is shaken for 24 hours at 20° C. in 10 g (1%) in an 80% aqueous solution (20% water) of either 2-butoxyethanol or 4-hydroxy-4-methyl-2-pentanone.

In general, the poly(urethane-acrylic) hybrids can be prepared by reacting an excess of diisocyanate with a polyol, dispersing the resulting polyurethane prepolymer in water. Also, the prepolymer generally contains carboxy groups. The prepolymers are then mixed with one or more vinyl monomers such as acrylates or styrene or substituted styrene monomers. Tertiary amines are added to the mixtures and they are dispersed in water, and oil-soluble initiators are added to begin polymerization. The resulting polymer hybrids are dispersed as colloidal particles. This dispersion is not merely a mixture or blend of a polyurethane dispersion and an acrylic emulsion. The urethane and acrylic polymerizations are completed concurrently. For example, the acrylic-urethane hybrid dispersion is anionically stabilized.

One specific synthetic method includes preparing a polyurethane dispersion, adding acrylic monomers and forming the acrylic polymer in the presence of the polyurethane dispersion, as described for example in U.S. Pat. No. 3,684,758 (Honig et al.) that is incorporated herein for its synthetic methods.

Another specific method includes dispersing the urethane prepolymer and acrylic monomers together in water and completing the urethane and acrylic polymerizations concurrently as described for example in U.S. Pat. Nos. 4,644,030 (Loewrigkeit et al.) and 5,173,526 (Vijayendran et al.) both of which are incorporated herein by reference for their synthetic methods.

Other details about manufacturing methods and properties of the poly(urethane-acrylic) hybrids are provided by Galgoci et al. in JCT Coatings Tech. 2(13), 28-36 (February 2005).

Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that may also include commercial surfactants, anti-foaming agents, dispersing agents, anti-corrosive agents, and optionally pigments and water-miscible organic solvents. Further details about each commercial Hybridur® polymer dispersion can be obtained by visiting the Air Products and Chemicals, Inc. website.

Still other useful particulate primary polymeric binders are polymers having polyalkylene oxide segments [such as poly(ethylene)oxide and poly(propylene)oxide segments] as described for example in U.S. Pat. Nos. 6,899,994 (Huang et al.) and 7,261,998 (Hayashi et al.) that are incorporated herein by reference for specific details about such polymers and methods of preparing them. Particular details of such polymeric binders are provided in Columns 6-13 of the noted Huang et al. patent and Columns 7-13 of the noted Hayashi et al. patent.

In general, such polymeric binders can be graft copolymers comprising a main chain polymer and polyalkylene oxide side chains, a block copolymer having at least one polyalkylene oxide block and at least one non-polyalkylene oxide block, and a combination thereof. For example, the graft copolymers can include recurring units having pendant -Q-W-Y groups wherein Q is a divalent linking group, W is either a hydrophilic or hydrophobic segment, and Y is a hydrophilic or hydrophobic segment with the proviso that when W is a hydrophilic segment, Y is either a hydrophobic or hydrophilic segment, and further that when W is a hydrophobic segment, Y is a hydrophilic segment. Such polymeric binders can also have additional recurring units that have pendant, alkyl, halogen, cyano, acyloxy, alkoxy, alkoxycarbonyl, hydroxyalkyloxycarbonyl, acyl, aminocarbonyl, or aryl groups, as described in more detail in the noted patent of Huang et al. The cyano pendant groups are particularly useful.

### Imaging and Processing

The lithographic printing plate precursors can have any useful form including, but not limited to, flat plates, printing cylinders, printing sleeves (solid or hollow cores) and printing tapes (including flexible printing webs).

Lithographic printing plate precursors can be of any size or shape (for example, square or rectangular) having the requisite one or more imagable layers disposed on a suitable substrate. Printing cylinders and sleeves are known as rotary printing members having a substrate and at least one imagable layer in cylindrical form. Hollow or solid metal cores can be used as substrates for printing sleeves.

During use, the lithographic printing plate precursors are exposed to a suitable source of imaging radiation at a wavelength of from about 300 to about 1500 nm and typically from about 750 to about 1250 nm. The lasers used for exposure are usually diode lasers, because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of from about 800 to about 850 nm or from about 1040 to about 1120 nm.

The imaging apparatus can function solely as a platesetter or it can be incorporated directly into a lithographic printing press. In the latter case, printing may commence immediately after imaging, thereby reducing press set-up time considerably. The imaging apparatus can be configured as a flatbed recorder or as a drum recorder, with the printing plate mounted to the interior or exterior cylindrical surface of the drum. Examples of useful infrared imaging apparatus are available as models of Kodak® Trendsetter imagesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm and the Screen PlateRite 4300 series or 8600 series platesetter (available from Screen, Chicago, Ill.). Additional useful sources of radiation include direct imaging presses that can be used to image a precursor while it is attached to the printing plate cylinder. An example of a suitable direct imaging printing press includes the Heidelberg SM74-DI press (available from Heidelberg, Dayton, Ohio).

Useful UV and “violet” imaging apparatus include Prosetter platesetters available from Heidelberger Druckmaschinen (Germany), Luxel Vx-9600 CTP and Luxel V-8 CTP platesetters available from Fuji Photo (Japan), Python platesetter (Highwater, UK), MakoNews, Mako 2, Mako 4, and Mako 8 platesetters available from ECRM (US), Micra platesetter available from Screen (Japan), Polaris and Advantage platesetters available from Agfa (Belgium), LaserJet platesetter available from Krause (Germany), and Andromeda® A750M platesetter available from Lithotech (Germany), Infrared imaging speeds may be in the range of from about 50 to about 1500 mJ/cm², and typically from about 75 to about 400 mJ/cm². Image radiation in the UV or “violet” region of the spectrum can be carried out generally using energies of at least 0.01 mJ/cm² and up to and including 0.5 ml/cm² and typically at least 0.02 and up to and including 0.1 mJ/cm².

While laser imaging is useful in the practice of this invention, imaging can be provided by any other means that provides thermal energy in an imagewise fashion. For example, imaging can be accomplished using a thermoresistive head (thermal printing head) in what is known as “thermal printing”, as described for example in U.S. Pat. No. 5,488,025 (Martin et al.) and as used in thermal fax machines and sublimation printers. Thermal print heads are commercially available (for example, as a Fujitsu Thermal Head FTP-040 MCS001 and TDK Thermal Head F415 HH7-1089).

Direct digital imaging is generally used for imaging. The image signals are stored as a bitmap data file on a computer. Raster image processor (RIP) or other suitable means may be used to generate such files. The bitmaps are constructed to define the hue of the color as well as screen frequencies and angles.

Imaging of the lithographic printing plate precursor produces a lithographic printing plate that comprises a latent image of imaged (exposed) and non-imaged (non-exposed) regions.

With or without a post-exposure baking (or pre-heat) step after imaging and before processing, the imaged lithographic printing plate precursors are processed “off-press” using a processing solution as described below. Processing the imaged element with the processing solution is carried out for a time sufficient to remove predominantly only the non-exposed regions of the imagable layer and underlying portions of any underlayers, and to reveal the hydrophilic surface of the substrate, but not long enough to remove significant amounts of the exposed regions. Thus, the lithographic printing plate precursors are “negative-working”. The revealed hydrophilic surface repels ink while the exposed (or imaged) regions accept ink. The non-imaged (non-exposed) regions of the imagable layer(s) are described as being “soluble” or “removable” in the processing solution because they are removed, dissolved, or dispersed within it more readily than the imaged (exposed) regions. Thus, the term “soluble” also means “dispersible”.

The single processing solution both “develops” the imaged precursors by removing predominantly only the non-exposed regions (development) and also provides a protective layer or coating over the entire imaged and developed surface. In this second aspect, the processing solution can behave somewhat like a gum that is capable of protecting the lithographic image on the printing plate against contamination or damage (for example, from oxidation, fingerprints, dust, or scratches).

There are generally two types of “gum” solutions known in the art: (1) a “bake”, “baking”, or “pre-bake” gum usually contains one or more compounds that do not evaporate at the usual pre-bake temperatures used for making lithographic printing plates, typically an anionic or nonionic surfactant, and (2) a “finisher” gum that usually contains one or more hydrophilic polymers (both synthetic and naturally-occurring, such as gum Arabic cellulosic compounds, (meth)acrylic acid polymers, and polysaccharides) that are useful for providing a protective overcoat on a printing plate. The processing solution used in the practice of this invention could be generally considered either type of gum.

By using the single processing solution described herein, the conventional aqueous alkaline developer compositions containing silicates or metasilicates, or various organic solvents, can be avoided. In some embodiments, processing solutions containing organic solvents are also avoided. If water-miscible solvents such as benzyl alcohol are present, they are present in an amount of up to 5 weight %. Other water-miscible solvents that may be present include but are not limited to, the reaction products of phenol with ethylene oxide and propylene oxide such as ethylene glycol phenyl ether (phenoxyethanol), esters of ethylene glycol and of propylene glycol with acids having six or fewer carbon atoms, and ethers of ethylene glycol, diethylene glycol, and of propylene glycol with alkyl groups having six or fewer carbon atoms, such as 2-ethoxyethanol and 2-butoxyethanol. A single organic solvent or a mixture of organic solvents can be used. By “water-miscible” we mean that the organic solvent or mixture of organic solvents is either miscible with water or sufficiently soluble in the processing solution that phase separation does not occur.

Moreover, one advantage of this invention is that once the processing solution is used in this manner, no separate rinsing step is necessary before using the resulting lithographic printing plate for printing. However, before printing, any excess processing solution may be removed from the lithographic printing plate by wiping or use of a squeegee or a pair of nip rollers in an apparatus, followed by optional drying using any suitable drying means.

The processing solution may be provided in diluted or concentrated form. The amounts of components described below refer to amounts in the diluted processing solution that is the most likely form for use in the practice of the invention. However, it is to be understood that the present invention includes the use of concentrated processing solutions and the amounts of various components (such as the anionic surfactants) would be correspondingly higher.

The processing solution used in the practice of this invention is an aqueous solution that generally has a pH greater than 2 and up to about 11, and typically from about 6 to about 11, or from about 6 to about 10.5, as adjusted using a suitable amount of an acid or base. The viscosity of the processing solution can be adjusted to a value of from about 1.7 to about 5 cP by adding a suitable amount of a viscosity-increasing compound such as a poly(vinyl alcohol) or poly(ethylene oxide).

Various components can be present in the single processing solution to provide the development and gumming functions, except for those components specifically excluded above.

For example, some of the single processing solutions have as an essential component, one or more anionic surfactants, even though optional components (described below) can be present if desired. Useful anionic surfactants include those with carboxylic acid, sulfonic acid, or phosphonic acid groups (or salts thereof). Anionic surfactants having sulfonic acid (or salts thereof) groups are particularly useful. For example, such anionic surfactants can include aliphates, abietates, hydroxyalkanesulfonates, alkanesulfonates, dialkylsulfosuccinates, alkyldiphenyloxide disulfonates, straight-chain alkylbenzenesulfonates, branched alkylbenzenesulfonates, alkylnaphthalenesulfonates, alkylphenoxypolyoxy-ethylenepropylsulfonates, salts of polyoxyethylene alkylsulfonophenyl ethers, sodium N-methyl-N-oleyltaurates, monoamide disodium N-alkylsulfosuccinates, petroleum sulfonates, sulfated castor oil, sulfated tallow oil, salts of sulfuric esters of aliphatic alkylester, salts of alkylsulfuric esters, sulfuric esters of polyoxy-ethylene alkylethers, salts of sulfuric esters of aliphatic monoglucerides, salts of sulfuric esters of polyoxyethylenealkylphenylethers, salts of sulfuric esters of polyoxyethylenestyrylphenylethers, salts of alkylphosphoric esters, salts of phosphoric esters of polyoxyethylenealkylethers, salts of phosphoric esters of polyoxyethylenealkylphenylethers, partially saponified compounds of styrene-maleic anhydride copolymers, partially saponified compounds of olefin-maleic anhydride copolymers, and naphthalenesulfonateformalin condensates. Alkyldiphenyloxide disulfonates (such as sodium dodecyl phenoxy benzene disulfonates), alkylated naphthalene sulfonic acids, sulfonated alkyl diphenyl oxides, and methylene dinaphthalene sulfonic acids) are particularly useful as the primary anionic surfactant. Such surfactants can be obtained from various suppliers as described in McCutcheon's Emulsifiers & Detergents, 2007 Edition.

Particular examples of such anionic surfactants include but are not limited to, sodium dodecylphenoxyoxybenzene disulfonate, the sodium salt of alkylated naphthalenesulfonate, disodium methylene-dinaphthalene disulfonate, sodium dodecylbenzenesulfonate, sulfonated alkyl-diphenyloxide, ammonium or potassium perfluoroalkylsulfonate and sodium dioctylsulfosuccinate.

The one or more anionic surfactants can be generally present in an amount of at least 1 weight %, and typically from about 5 weight % or from about 8 weight % and up to about 45 weight %, or up to about 30 weight % (% solids). In some embodiments, the one or more anionic surfactants can be present in an amount of from about 8 to about 20 weight %.

Two or more anionic surfactants (“first”, “second”, etc.) can also be used in combination. In such mixtures, a first anionic surfactant, such as an alkyldiphenyloxide disulfonate, can be present generally in an amount of at least 1 weight % and typically from about 5 to about 20 weight %. A second surfactant can be present (same or different from the first anionic surfactant) in a total amount of at least 1 weight %, and typically from about 3 to about 20 weight %. Second or additional anionic surfactants can be selected from the substituted aromatic alkali alkyl sulfonates and aliphatic alkali sulfates. One particular combination of anionic surfactants includes one or more alkyldiphenyloxide disulfonates and one or more aromatic alkali alkyl sulfonates (such as an alkali alkyl naphthalene sulfonate).

The single processing solutions useful in this invention may optionally include nonionic surfactants as described in [0029] or hydrophilic polymers described in [0024] of EP 1,751,625 (noted above), incorporated herein by reference. Particularly useful nonionic surfactants include Mazol® PG031-K (a triglycerol monooleate, Tween® 80 (a sorbitan derivative), Pluronic® L62LF (a block copolymer of propylene oxide and ethylene oxide), and Zonyl® FSN (a fluorocarbon), and a nonionic surfactant for successfully coating the processing solution onto the printing plate surface, such as a nonionic polyglycol. These nonionic surfactants can be present in an amount of up to 10 weight %, but at usually less than 2 weight % (% solids).

Other optional components of the single processing solution include inorganic salts (such as those described in [0032] of U.S. Patent Application Publication 2005/0266349, noted above), wetting agents (such as a glycol), metal chelating agents, antiseptic agents, organic amines, anti-foaming agents, ink receptivity agents (such as those described in [0038] of U.S. '349), and viscosity increasing agents as noted above. Useful amounts of such components are known in the art from their use in traditional alkaline developers or gum solutions. Other useful addenda include but not limited to, phosphonic acids or polycarboxylic acids, or salts thereof that are different than the anionic surfactants described above. Such acids can be present in an amount of at least 0.001 weight % and typically from about 0.001 to about 10 weight % (% solids), and can include but are not limited to, polyaminopolycarboxylic acids, aminopolycarboxylic acids, or salts thereof, [such as salts of ethylenediaminetetraacetic acid (EDTA, sodium salt)], organic phosphonic acids and salts thereof, and phosphonoalkanetricarboxylic acids and salts thereof.

Generally, after imaging, the single processing solution is applied to the imaged precursor by rubbing, spraying, jetting, dipping, immersing, coating, or wiping the outer layer with the single processing solution or contacting the imaged precursor with a roller, impregnated pad, or applicator containing the single processing solution. For example, the imaged element can be brushed with the processing solution, or the processing solution can be poured onto or applied by spraying the imaged surface with sufficient force to remove the exposed regions using a spray nozzle system as described for example in [0124] of EP 1,788,431A2 (noted above). Still again, the imaged element can be immersed in the single processing solution and rubbed by hand or with an apparatus.

The single processing solution can also be applied in a processing unit (or station) as a component of a suitable apparatus that has at least one roller for rubbing or brushing the precursor while the single processing solution is applied. By using such a processing unit, the exposed regions of the imaged layer may be removed from the substrate more completely and quickly. Residual single processing solution may be removed (for example, using a squeegee or nip rollers) or left on the resulting printing plate (and dried) without any rinsing step. It is desirable that processing be carried out using processor systems and apparatus that allow the processing solution to reside on the imaged precursor for sufficient time of interaction between the processing solution and the precursor imaged coatings before mechanical means (such as brush or plush rollers) are used.

Excess single processing solution can be collected in a tank and used several times, and replenished if necessary from a reservoir of “fresh” single processing solution. A replenisher solution can be of the same concentration as that used during processing, it can be provided in concentrated form and diluted with water at an appropriate time, or it can be comprise an entirely different composition. It may also be desirable to apply a “fresh” sample of the processing solution to each imaged lithographic printing plate precursor.

Following processing, the resulting lithographic printing plate can be used for printing without any need for a separate rinsing step using water.

The resulting lithographic printing plates can also be baked in a postbake operation that can be carried out to increase run length. Baking can be carried out, for example, in a suitable oven at a temperature of less than 300° C. and typically at less than 250° C. for from about 2 to about 10 minutes. More typically, the baking is done very quickly at a temperature of from about 160° C. to about 220° C. (for example, at 190° C.) for up to five minutes (for example, up to two minutes). In some embodiments, the lithographic printing plates are postbaked at from about 160 to about 220° C. for up to two minutes

Alternatively, the lithographic printing plates can be baked or cured by overall exposure to IR radiation at a wavelength of from about 800 to about 850 nm. This exposure creates conditions that enable very controllable baking effects with minimal distortion. For example, the lithographic printing plates can be passed through a commercial QuickBake 1250 oven (available from Eastman Kodak Company) at 4 feet (1.3 m) per minute at the 45% power setting of an infrared lamp to achieve a similar baking result from heating the plate in an oven at 200° C. for 2 minutes.

A lithographic ink and fountain solution can be applied to the printing surface of the lithographic printing plate for printing. The non-exposed regions of the outermost layer take up ink and the hydrophilic surface of the substrate revealed by the imaging and processing takes up the fountain solution. The ink is then transferred to a suitable receiving material (such as cloth, paper, metal, glass, or plastic) to provide one or more desired impressions of the image thereon. If desired, an intermediate “blanket” roller can be used to transfer the ink from the printing plate to the receiving material. The printing plates can be cleaned between impressions, if desired, using conventional cleaning means and chemicals.

The following examples are presented to illustrate the practice of this invention but are not intended to be limiting in any manner.

### EXAMPLES

### Materials and Methods

850S Plate Finisher (pH 2.1) is available from Eastman Kodak Company (Rochester, N.Y.).

BLO represents γ-butyrolactone.

Crystal Violet is a violet dye C.I. 42555; CAS 548-62-9 [(p-(CH₃)₂NC₆H₄)₃C⁺Cl⁻] that is available from Aldrich (Milwaukee, Wis.).

DMAC represents N,N-dimethylacetamide.

FluorN™ 2900 is a fluorosurfactant that was obtained from Cytonix Corporation (Beltsville, Md.).

G716 is a finisher gum solution as supplied by Eastman Kodak Company (pH 2.7).

Gum N1 (also N1 finisher gum) is a prebake gum consisting of MX1591 (980 parts) and EDTA tetrasodium salt (20 parts) and had a pH of 9.4.

Gum O1 is a prebake gum consisting of MX1591 (985 parts) and EDTA tetrasodium salt (15 parts) and had a pH of 8.7.

Hybridur® 580 is a urethane-acrylic hybrid polymer dispersion (40%) that was obtained from Air Products and Chemicals, Inc. (Allentown, Pa.).

IB05 represents bis(4-t-butylphenyl)iodonium tetraphenylborate.

IPA represents iso-propyl alcohol.

IRT is an IR dye having the following structure and obtained from Showa Denko, Tokyo, Japan:

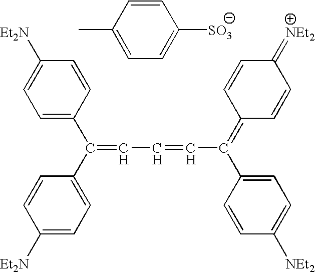

Masurf® FS-1520 is a fluoroaliphatic betaine fluorosurfactant that was obtained from Mason Chemical Company (Arlington Heights, Ill.).

MEK represents methyl ethyl ketone.

MX1591 is a prebake gum solution that is available from Eastman Kodak (Rochester, N.Y.).

NK Ester A-DPH is a dipentaerythritol hexaacrylate that was obtained from Kowa American (New York, N.Y.).

NPB 269 is a copolymer of methyl methacrylate/PEGMA/vinyl carbazole/acrylonitrile/methacrylic acid/vinyl allyl at 22.2/0.4/4.7/41.8/16.2/14.7 mol % (acid number of 111 mg KOH/g) that was prepared by radical polymerization of the first five monomers followed by the reaction between the precursor and allyl bromide using conditions and reactants known to the skilled in the art.

PEGMA represents poly(ethylene glycol) methyl ether methacrylate (50% water) that was obtained from Aldrich Chemical Company (Milwaukee, Wis.).

Phosmer PE is an ethylene glycol methacrylate phosphate with 4-5 ethoxy groups that was obtained from Uni-Chemical Co. Ltd. (Japan).

PGME represents 1-methoxypropan-2-ol (available as Dowanol® PM).

Pigment 951 is a 27% solids dispersion of 7.7 parts of a poly(vinyl acetal) derived from poly(vinyl alcohol) acetalized with acetaldehyde, butyraldehyde, and 4-formylbenzoic acid, 76.9 parts of Irgalith Blue GLVO (Cu-phthalocyanine C.I. Pigment Blue 15:4), and 15.4 parts of Disperbyk® 167 dispersant (Byk Chemie) in 1-methoxy-2-propanol.

Polymer 1 was a copolymer of PEGMA/acrylonitrile/styrene/acrylic acid at 10/60/21.5/8.5 wt. % (acid number=74 mg KOH/g) that was prepared by radical polymerization using conditions and reactants known to one skilled in the art.

Polymer 2 was a copolymer of PEGMA/acrylonitrile/styrene/acrylic acid at 10/60/21.5/8.5 wt. % (20.9% solids in n-propanol/water (76:24), acid number=68 mg KOH/g) that was prepared by radical polymerization using conditions and reactants known to one skilled in the art.

Polymer 3 was a copolymer of methyl methacrylate/vinyl carbazole/acrylonitrile/styrene/methacrylic acid/allyl bromide at 12.3/9.5/48.4/12.3/17.5 wt. % (acid number=82 mg KOH/g) that was prepared by radical polymerization of the first four monomers using conditions and reactants known to one skilled in the art, followed by reaction of the prepared precursor with allyl bromide.

Polymer 4 was a polymer dispersion of PEGMA/acrylonitrile/styrene/acrylic acid at 10/70/15/5 wt. % (15% solid in n-propanol/water=76/24, acid number=36.4 mg KOH/g) that was prepared by emulsion polymerization using conditions and reactants known to one skilled in the art.

Polymer 5 was a copolymer of acrylonitrile/methacrylamide/N-phenyl maleimide/acrylic acid at 48/23.4/15.6/13 wt. % (acid number=81 mg KOH/g) that was prepared by radical polymerization using conditions and reactants known to one skilled in the art.

Polymer 6 was a copolymer of acrylonitrile/methacrylamide/N-phenyl maleimide/acrylic acid at 48/20.4/13.6/18 wt % (acid number=111 mg KOH/g) that was prepared by radical polymerization using conditions and reactants known to one skilled in the art.

PVA405 is a poly(vinyl alcohol) having a hydrolysis degree of 80% that was obtained from Kuraray (Japan).

RC510 is a washout storage gum that was obtained from Agfa Corporation, Ridgefield Park, N.J. (pH 7.5).

Rhoplex WL-91 is a polyacrylate emulsion (42% in water) that was obtained from Rohm Haas, USA.

S0507 is an IR dye that was obtained from FEW Chemicals GmbH (Germany):

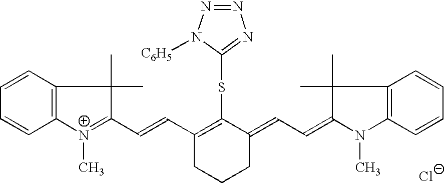

SP 2-in-1 is a subtractive plate developer/finisher as supplied by Eastman Kodak Company.

SR399 is dipentaerythritol pentaacrylate that was obtained from Sartomer Company, Inc (Exton, Pa.).

SR-499 is ethoxylated (6) trimethylolpropane triacrylate that was obtained from Sartomer Company, Inc.

Thermotect is a baking gum solution that was obtained from TechNova (Mahalaxmi, Mumbai 400 011, India).

UV plate cleaner was obtained from Allied Pressroom Chemistry, Inc. (Hollywood, Fla.).

Varn Litho Etch 142W fountain solution was obtained from Varn International (Addison, Ill.).

Varn-120 plate cleaner was also obtained from Varn International.

Varn PAR alcohol replacement was obtained from Varn International.

The “DH Test” used in the examples was a dry-heat accelerated aging test carried out at 48° C. for 5 days.

The “RH Test” used in the examples was a high humidity accelerated aging test carried out at 38° C. and a relative humidity of 85% for 5 days.

### Invention Example 1

A negative-working imagable layer formulation was prepared by mixing 3.7 g of the Polymer 2 dispersion, 0.2 g of SR499, 0.4 g of SR399, 0.4 g of NK ester A-DPH, 0.1 g of Phosmer PE, 0.15 g of IB-05, 0.05 g of S0507, 0.03 g of Crystal Violet, and 0.4 g of FluorN™ 2900 (5% in PGME) in 4 g of n-propanol, 4 g of PGME, 3 g of MEK, 1 g of methanol, and 1 g of water. In the formulation, Polymer 2 remained in particulate form.

This imagable layer formulation was applied to an electrochemically grained and sulfuric acid anodized aluminum substrate that had been post-treated with poly(vinyl phosphonic acid) to provide a dry coating weight of about 1.2 g/m². On the resulting imagable layer, a topcoat formulation comprising 4 g of PVA405, 4 g of IPA, 90 g of water, and 2 g of Masurf® FS-1520 solution (1% in water) was applied to provide a dry coating topcoat weight of about 0.4 g/m². Both the imagable and topcoat formulations were applied using a wire-wound rod and sequentially dried for approximately 60 seconds in a Ranar conveyor oven set at 120° C.

Samples of the resulting negative-working lithographic printing plate precursor were imaged with a power series from 10 to 100 mJ/cm² on a Kodak Trendsetter® 3244× image setter by exposure to an 830 nm IR laser, and was then developed manually with gentle scrubbing. The imaged lithographic printing plates were then developed for 20 seconds individually in Gum N1 solution at 25° C., 30 seconds in Gum O1 solution at 25° C., and 10 seconds in SP 2-in-1/H₂O (1/6) solution at 20° C. to provide satisfactory images. The minimum energy to achieve a solid image was about 40 to 50 mJ/cm² for each element.

### Comparative Example 1

Polymer 1 had same chemical composition as Polymer 2 but was dissolved in a solvent mixture of DMAC/PGME/MEK=2.5/2/4.5 before formulating. A negative-working imagable layer formulation was prepared by dissolving 7.7 g of the Polymer 1 solution (10%), 0.2 g of SR499, 0.4 g of SR399, 0.4 g of NK ester A-DPH, 0.1 g of Phosmer PE, 0.15 g of IB-05, 0.05 g of S0507, 0.03 g of Crystal Violet, and 0.4 g of FluorN™ 2900 (5% in PGME) in 2.5 g of DMAC, 2 g of PGME and 4.5 g of MEK.

This imagable layer formulation was applied to a substrate as described in Invention Example 1 to provide a dry coating weight of about 1.2 g/m². On the resulting imagable layer, the topcoat formulation of Invention Example 1 was applied at the same coverage. Both formulations were applied and dried as described in Invention Example 1.

The resulting negative-working lithographic printing plate precursor was imaged with a power series from 10 to 100 mJ/cm² on a Kodak Trendsetter® 3244× image setter by exposure to an 830 nm IR laser, and was then developed manually with gentle scrubbing. This imaged printing plate was not developable after more than 1 minute in any of Gum N1 and Gum O1 solutions at 25° C., or in SP 2-in-1/H₂O (1/6) solution at 20° C.

### Invention Example 2

A negative-working imagable layer formulation was prepared by mixing 1.8 g Rhoplex WL-91 (42% in water), 0.2 g of SR499, 0.4 g of SR399, 0.4 g of NK ester A-DPH, 0.1 g of Phosmer PE, 0.15 g of IB-05, 0.05 g of IRT, and 0.4 g of FluorN™ 2900 (5% in PGME) in 8 g of n-propanol, 5 g of PGME, and 1.5 g of water. In the formulation, the polymer in Rhoplex WL-91 remained in particulate form.

This imagable layer formulation was applied to a substrate as described in Invention Example 1. On the resulting imagable layer, the topcoat formulation of Invention Example 1 was applied. Both formulations were applied and dried as described in Invention Example 1.

The resulting negative-working lithographic printing plate precursor was imaged with a power series from 10 to 100 mJ/cm² on a Kodak Trendsetter® 3244× image setter by exposure to an 830 nm IR laser, and was then developed manually with gentle scrubbing. This imaged lithographic printing plate was developed in 20 seconds in Gum N1 solution at 20° C. The minimum energy to achieve a solid image was about 70 mJ/cm².

### Comparative Example 2

A negative-working imagable layer formulation was prepared by dissolving 1.8 g Rhoplex WL-91 (42% in water), 0.2 g of SR499, 0.4 g of SR399, 0.4 g of NK ester A-DPH, 0.1 g of Phosmer PE, 0.15 g of IB-05, 0.05 g of IRT, and 0.4 g of FluorN™ 2900 (5% in PGME) in 1.5 g of BLO, 8 g of MEK, 2.5 g of PGME, 1 g of methanol, and 0.5 g of water. In this formulation, Rhoplex WL-91 particles were dissolved and formed a homogenous solution.

The imagable layer formulation was applied to a substrate as described in Invention Example 1. On the resulting imagable layer, the topcoat formulation of Invention Example 1 was applied. Both formulations were applied and dried as described in Invention Example 1.

The resulting negative-working lithographic printing plate precursor was imaged with a power series from 10 to 100 mJ/cm² on a Kodak Trendsetter® 3244× image setter by exposure to an 830 nm IR laser, and was then developed manually with gentle scrubbing in Gum N1. This imaged element failed to develop in 60 seconds in Gum N1 at 20° C.

### Invention Example 3

A negative-working imagable layer formulation was prepared by mixing 0.47 g of Hybridur® 580 dispersion (40% in water), 5.8 g of NPB-269 solution (10% in BLO/PGME/MEK/H2O=1/2/5/1), 0.2 g of SR499, 0.4 g of SR399, 0.4 g of NK ester A-DPH, 0.1 g of Phosmer PE, 0.15 g of IB-05, 0.05 g of S0507, 0.5 g of Pigment 951, and 0.4 g of FluorN™ 2900 (5% in PGME) in 1.5 of BLO, 1.5 g of PGME, 5.5 g of MEK, 1 g of methanol, and 0.5 g of water. In the formulation, the polymer in Hybridur® 580 remained in particulate form.

This imagable layer formulation was applied to a substrate as described in Invention Example 1. On the resulting imagable layer, the topcoat formulation of Invention Example 1 was applied. Both formulations were applied and dried as described in Invention Example 1.

The resulting negative-working lithographic printing plate precursor was imaged with a power series from 10 to 100 mJ/cm² on a Kodak Trendsetter® 3244× image setter by exposure to an 830 nm IR laser, and was then developed manually with gentle scrubbing. This imaged element was developed in 7 seconds in Gum N1 at 20° C., and in 10 seconds in Gum O1 at 20° C. The minimum energy to achieve a solid image was about 25 mJ/cm².

Another sample of the precursor was imaged at an exposure of 90 mJ/cm² and developed in Gum N1 at 20° C. with gentle scrubbing for 10 seconds. The developed lithographic printing plate was tested on a Miehle sheet-fed press using wear ink containing 1.5% calcium carbonate and a fountain solution of Varn Litho Etch 142W at 3 oz./gal (23.4 ml/liter) and PAR alcohol replacement at 3 oz./gal (23.4 ml/liter). A chemical resistance test was performed after 5,000 impressions by applying UV plate cleaner and Varn-120 plate cleaner in different areas to the image of the plate and resuming the printing without any cleaning after 10-15 minutes. At the 90 mJ/cm² exposure energy, the image recovered after 10 impressions and did not show any degradation from the plate cleaners. At the end of the workday, the printing plate was cleaned with Aqua-image cleaner/preserver and left mounted on the press for one night. Upon start-up the following morning, the printing plate performed identically to the previous evening. At the fully wearing condition, the printing plate did not show any solid wear after 35,000 impressions. This printing plate also passed both “DH” and “RH” tests identified above without a reduction in plate developability and speed.

### Invention Example 4

A negative-working imagable layer formulation was prepared by mixing 1.9 g of Polymer 4 dispersion, 4.9 of NPB-269 solution (10% in BLO/PGME/MEK/H2O=1/2/5/1), 0.2 g of SR499, 0.4 g of SR399, 0.4 g of NK ester A-DPH, 0.1 g of Phosmer PE, 0.15 g of IB-05, 0.05 g of S0507, 0.5 g of Pigment 951, and 0.4 g of FluorN™ 2900 (5% in PGME) in 1.5 of BLO, 1.5 g of PGME, 5.5 g of MEK, 1 g of methanol, and 0.5 g of water. In the formulation, the Polymer 4 remained in particulate form.

The imagable layer formulation was applied to a substrate as described in Invention Example 1. On the resulting imagable layer, the topcoat formulation of Invention Example 1 was applied. Both formulations were applied and dried as described in Invention Example 1.

The resulting lithographic printing plate precursor was imaged with a power series from 10 to 100 mJ/cm² on a Kodak Trendsetter® 3244× image setter by exposure to an 830 nm IR laser, and was then developed manually with gentle scrubbing for 5 seconds in Gum N1 at 20° C., and in 10 seconds in Gum O1 at 20° C. The minimum energy to achieve a solid image was about 30 mJ/cm².

### Comparative Example 3

A negative-working imagable layer formulation was prepared by dissolving 7.7 g of Polymer 3 solution (10% in BLO/PGME/MEK/H₂O at 1/2/5/1), 0.2 g of SR499, 0.4 g of SR399, 0.4 g of NK ester A-DPH, 0.1 g of Phosmer PE, 0.15 g of IB-05, 0.05 g of S0507, 0.5 g of Pigment 951, and 0.4 g of FluorN™ 2900 (5% in PGME) in 1.5 of BLO, 1.5 g of PGME, 4.5 g of MEK, 1 g of methanol, and 0.5 g of water.

The imagable layer formulation was applied to a substrate as described in Invention Example 1. On the resulting imagable layer, the topcoat formulation of Invention Example 1 was applied. Both formulations were applied and dried as described in Invention Example 1.

The resulting lithographic printing plate precursor was imaged with a power series from 10 to 100 mJ/cm² on a Kodak Trendsetter® 3244× image setter by exposure to an 830 nm IR laser, and was then developed manually with gentle scrubbing. Although the imaging layer contained a polymeric binder having a similar acid number to the polymeric binders used in the imaging layers of Invention Examples 3 and 4, this imaged element failed to develop in 60 seconds in both Gum NI and Gum O1 at 20° C.

### Invention Example 5

A negative-working imagable layer formulation was prepared by mixing 2.1 g of Polymer 4 dispersion, 4.6 g of Polymer 6 solution (10% in BLO/PGME/MEK/H₂O=1.5/1.5/4.5/2), 0.2 g of SR499, 0.4 g of SR399, 0.4 g of NK ester A-DPH, 0.1 g of Phosmer PE, 0.15 g of IB-05, 0.05 g of S0507, 0.5 g of Pigment 951, and 0.4 g of FluorN™ 2900 (5% in PGME) in 1.5 of BLO, 1.5 g of PGME, 5.5 g of MEK, 1 g of methanol, and 0.5 g of water. In this formulation, Polymer 4 remained in particulate form.

The imagable layer formulation was applied to a substrate as described in Invention Example 1. On the resulting imagable layer, the topcoat formulation of Invention Example 1 was applied. Both formulations were applied and dried as described in Invention Example 1.

The resulting lithographic printing plate precursor was imaged with a power series from 10 to 100 mJ/cm² on a Kodak Trendsetter® 3244× image setter by exposure to an 830 nm IR laser, and was then developed manually with gentle scrubbing. This precursor showed excellent development in various gum solutions as shown below in TABLE I.

TABLE I

| | Invention Example 5 | | | | | | |
|---|---|---|---|---|---|---|---|
| | | | | Minimum | Comparative Example 4 | | |
| | Developing | Developing | | Energy for | Developing | Developing | |
| Processing | Temperature | Time | Background | Solid Image | Temperature | Time | Background |
| Solutions | (° C.) | (seconds) | Cleanness | (mJ/cm²) | (° C.) | (seconds) | Cleanness |
| 850S/N1 | 20 | 5 | Clean | 20 | 20 | >60 | Stain |
| (1/1) | | | | | | | |
| 850S/O1 | 20 | 15 | Clean | 20 | 20 | >60 | Dirty |
| (1/1) | | | | | | | |
| RC 510 | 35 | 5 | Clean | 20 | 35 | >60 | Stain |
| | 30 | 10 | Clean | 20 | 30 | >>60 | Stain |
| | 25 | 15 | Clean | 20 | 25 | >>60 | Stain |
| Thermotect | 20 | 5 | Clean | 20 | 20 | >30 | Stain |
| G716 | 35 | 7 | Clean | 20 | 35 | >60 | Dirty |
| | 30 | 12 | Clean | 20 | 30 | >60 | Dirty |

### Comparative Example 4

A negative-working imagable layer formulation was prepared by dissolving 7.7 g of Polymer 5 solution (10% in BLO/PGME/MEK/H2O=1.5/1.5/4.5/2), 0.2 g of SR499, 0.4 g of SR399, 0.4 g of NK ester A-DPH, 0.1 g of Phosmer PE, 0.15 g of IB-05, 0.05 g of S0507, 0.5 g of Pigment 951, and 0.4 g of FluorN™ 2900 (5% in PGME) in 1.5 of BLO, 1.5 g of PGME, 5.5 g of MEK, 1 g of methanol, and 0.5 g of water.

The imagable layer formulation was applied to a substrate as described in Invention Example 1. On the resulting imagable layer, the topcoat formulation of Invention Example 1 was applied. Both formulations were applied and dried as described in Invention Example 1.

The resulting lithographic printing plate precursor was imaged with a power series from 10 to 100 mJ/cm² on a Kodak Trendsetter® 3244× image setter by exposure to an 830 nm IR laser, and was then developed manually with gentle scrubbing. Although the polymeric binder in the imagable layer of this element had a similar acid number to the polymeric binder in the imagable layer of Invention Example 5, the resulting imaged element showed very poor developability in various gum solutions as shown in TABLE I shown above.

The invention has been described in detail with particular reference to certain preferred embodiments thereof, but it will be understood that variations and modifications can be effected within the spirit and scope of the invention.

1. A method of making an image comprising:
A) imagewise exposing a negative-working lithographic printing plate precursor using imaging radiation to provide both exposed and non-exposed regions in the imagable layer,
said lithographic printing plate precursor comprising a substrate and having thereon an imagable layer comprising:
a free-radically polymerizable component,
an initiator composition that is capable of generating free radicals sufficient to initiate polymerization of said free-radically polymerizable component upon exposure to said imaging radiation,
a radiation absorbing compound, and
a primary polymeric binder that is present in the form of discrete particles that are distributed throughout said imagable layer, and
B) applying a single processing solution to said imaged precursor both (1) to remove predominantly only said non-exposed regions, and (2) to provide a protective coating over all of said exposed and non-exposed regions of the resulting lithographic printing plate,
said single processing solution having a pH of from about 2 to about 11 and comprising at least 0.1 weight % of an anionic surfactant.

2. The method of claim 1 wherein said primary polymeric binder comprises particles of a poly(urethane-acrylic) hybrid, a polymer having polyalkylene oxide segments, or a polymer having a backbone comprising multiple urethane moieties and free radically polymerizable sides chains.

3. The method of claim 1 wherein said particles of said primary polymeric binder are present in an amount of from about 10 to about 70% based on total imagable layer dry weight.

4. The method of claim 1 wherein said particles of said primary polymeric binder have an average diameter of from about 30 to about 2000 nm.

5. The method of claim 1 wherein said imagable layer further comprises a secondary polymeric binder that is present in an amount of from about 1.5 to about 40% based on total imagable layer dry weight.

6. The method of claim 1 wherein said initiator composition comprises an onium salt.

7. The method of claim 1 wherein said radiation absorbing compound is an infrared radiation absorbing compound.

8. The method of claim 1 wherein said single processing solution consists essentially of from about 1 to about 45 weight % of one or more anionic surfactants.

9. The method of claim 1 further comprising:
C) removing excess single processing solution from said lithographic printing plate using a squeegee or nip rollers, and optionally drying said lithographic printing plate.

10. The method of claim 1 further comprising after step B), baking said lithographic printing plate at from about 160 to about 220° C. for up to two minutes.

11. The method of claim 1 wherein said single processing solution includes at least 0.001 weight % of an organic phosphonic acid or polycarboxylic acid, or a salt of either acid that is different than said anionic surfactant.

12. The method of claim 11 wherein said single processing solution further includes from about 0.001 to about 10 weight % of a salt of a polycarboxylic acid.

13. The method of claim 1 wherein said single processing solution comprises from about 5 to about 45 weight % of one or more anionic surfactants, at least one of which is an alkyldiphenyloxide disulfonate, and optionally comprising from about 8 to about 20 weight % of an alkali alkyl naphthalene sulfonates.

14. The method of claim 1 wherein said processing solution has a pH of from about 6 to about 10.5.

15. The method of claim 1 wherein said processing solution comprises organic solvents at less than 5 weight %.

16. The method of claim 1 wherein said lithographic printing plate precursor further comprises a water-soluble topcoat disposed over said imagable layer.

17. A method of lithographic printing comprising:
A) imagewise exposing a negative-working lithographic printing plate precursor using imaging radiation to provide both exposed and non-exposed regions in the imagable layer,
said lithographic printing plate precursor comprising a substrate and having thereon an imagable layer comprising:
a free-radically polymerizable component,
an initiator composition that is capable of generating free radicals sufficient to initiate polymerization of said free-radically polymerizable component upon exposure to said imaging radiation,
a radiation absorbing compound, and
a primary polymeric binder that is present in the form of discrete particles that are distributed throughout said imagable layer,
B) applying a single processing solution to said imaged precursor both (1) to remove predominantly only said non-exposed regions, and (2) to provide a protective coating over all of said exposed and non-exposed regions of the resulting lithographic printing plate,
said single processing solution having a pH of from about 2 to about 11 and comprising at least 0.1 weight % of an anionic surfactant,
C) removing excess single processing solution from said lithographic printing plate, and optionally drying said lithographic printing plate, and
D) without removing said protective coating, using said lithographic printing plate for printing an image using a lithographic printing ink.

18. The method of claim 17 wherein excess single processing solution is removed using a squeegee or nip rollers.

19. The method of claim 17 wherein said lithographic printing plate precursor is sensitive to infrared radiation, and said radiation absorbing compound is an infrared radiation absorbing dye.

20. The method of claim 17 wherein said single processing solution has a pH of from about 6 to about 10.5, and comprises organic solvents at less than 5 weight %, from about 8 to about 30 weight % of an alkyldiphenyloxide disulfonate, and optionally from about 8 to about 20 weight % of an alkali naphthalene sulfonates, and optionally from about 0.001 to about 10 weight % of a salt of a polycarboxylic acid.

21. The method of claim 17 wherein said primary polymeric binder comprises particles of a poly(urethane-acrylic) hybrid, a polymer having polyalkylene oxide segments, or a polymer having a backbone comprising multiple urethane moieties and free radically polymerizable sides chains, or a polymer having polyalkylene oxide segments, and optionally a secondary polymeric binder that comprises recurring units derived from one or more of monomers with pendant carboxy group, (meth)acrylates, styrene and styrene derivatives, vinyl acetate, N-substituted cyclic imides, maleic anhydride, vinyl carbazoles, monomers with multiple vinyl groups, (meth)acrylonitriles, (meth)acrylamides, poly(alkylene glycols), poly(alkylene glycol) (meth)acrylates, and N-substituted (meth)acrylamides.
